(19) United States
(12) Patent Application Publication
(10) Pub. No.: US 2026/0256011 A1
(43) Pub. Date: Aug. 27, 2026

(54) CHIP STACKED STRUCTURE, PACKAGE STRUCTURE, AND ELECTRONIC DEVICE

(71) Applicant: CXMT Corporation, Hefei (CN)

(72) Inventors: Quan WANG, Hefei (CN); Hengrong SHI, Hefei (CN)

(21) Appl. No.: 19/426,095

(22) Filed: Dec. 19, 2025

Related U.S. Application Data
(63) Continuation of application No. PCT/CN2025/122467, filed on Sep. 19, 2025.

(30) Foreign Application Priority Data
Feb. 26, 2025 (CN) 202510223495.2

(51) Int. Cl. H10W 72/90; H10W 72/00; H10W 90/00; H10W 90/24

(52) U.S. Cl. CPC H10W 72/9445; H10W 90/24; H10W 72/884; H10W 90/732; H10W 90/734; H10W 90/754

(57) ABSTRACT

A chip stacked structure, a package structure, and an electronic device are provided. In a first direction, a second chip located on an even-numbered layer is offset from a first chip located on an odd-numbered layer to expose multiple first signal pads on the first chip on the odd-numbered layer, and the multiple first signal pads are arranged in a second direction; in the second direction, the second chip located on the even-numbered layer is offset from the first chip located on the odd-numbered layer to expose multiple first common pads on the first chip on the odd-numbered layer, the multiple first signal pads are arranged in the first direction; and the first direction is perpendicular to the second direction; and multiple second common pads on the second chip are arranged in the first direction, and a lead between one of the first common pads and one of the second common pads is perpendicular to the first direction.

### CROSS REFERENCE TO RELATED APPLICATIONS

This application is a continuation of International Patent Application No. PCT/CN2025/122467, filed on Sep. 19, 2025, which claims the benefit of Chinese Patent Application No. 202510223495.2 titled “CHIP STACKED STRUCTURE, PACKAGE STRUCTURE, AND ELECTRONIC DEVICE”, filed with the China National Intellectual Property Administration (CNIPA) on Feb. 26, 2025, the disclosures of which are incorporated herein by reference in their entireties.

### TECHNICAL FIELD

Embodiments of the present disclosure relate to the field of semiconductor technologies, and in particular, to a chip stacked structure, a package structure, and an electronic device.

### BACKGROUND

A semiconductor product requires large-capacity data processing, and the volume thereof gradually decreases. However, as a quantity of stacked semiconductor chips increases, an electrical connection between the semiconductor chips becomes complex.

### SUMMARY

According to a first aspect of the embodiments of the present disclosure, a chip stacked structure is provided, where:
in a first direction, a second chip located on an even-numbered layer is offset from a first chip located on an odd-numbered layer to expose multiple first signal pads on the first chip on the odd-numbered layer, and the multiple first signal pads are arranged in a second direction;
in the second direction, the second chip located on the even-numbered layer is offset from the first chip located on the odd-numbered layer to expose multiple first common pads on the first chip on the odd-numbered layer, the multiple first signal pads are arranged in the first direction, and the first direction is perpendicular to the second direction; and
multiple second common pads on the second chip are arranged in the first direction, the multiple second common pads are located on an edge that is of the second chip and that is close to the first common pads, each of the first common pads is corresponding to each of the second common pads, and a lead between one of the first common pads and one of the second common pads is perpendicular to the first direction.

According to a second aspect of the embodiments of the present disclosure, a package structure is provided and includes:
a package substrate, including multiple substrate common pads; and
multiple chips, stacked on the package substrate;
in a first direction, a second chip located on an even-numbered layer being offset from a first chip located on an odd-numbered layer to expose multiple first signal pads on the first chip on the odd-numbered layer, and the multiple first signal pads being arranged in a second direction;
in the second direction, the second chip located on the even-numbered layer being offset from the first chip located on the odd-numbered layer to expose multiple first common pads on the first chip on the odd-numbered layer, the multiple first signal pads being arranged in the first direction, and the first direction being perpendicular to the second direction;
multiple second common pads on the second chip being arranged in the first direction, the multiple second common pads being located on an edge that is of the second chip and that is close to the first common pads, each of the first common pads corresponding to each of the second common pads, and a lead between one of the first common pads and one of the second common pads being perpendicular to the first direction; and
each of the substrate common pads corresponding to each of the first common pads, and a lead between each of the substrate common pads and each of the first common pads being perpendicular to the first direction.

### BRIEF DESCRIPTION OF DRAWINGS

FIG. 1 is a schematic diagram of a chip stacked structure according to an example embodiment;

FIG. 2 is a cross-sectional view of FIG. 1 in an X direction according to an example embodiment;

FIG. 3 is a cross-sectional view of FIG. 1 in a Y direction according to an example embodiment;

FIG. 4 is a top view of FIG. 1 in an X/Y direction according to an example embodiment;

FIG. 5 is a schematic diagram of offset between a first chip and a second chip according to an example embodiment;

FIG. 6 is a schematic diagram of a first ground pad/a second ground pad according to an example embodiment;

FIG. 7 is a schematic diagram of offset between a first chip and a second chip according to an example embodiment;

FIG. 8 is a cross-sectional view of a chip stacked structure in an X direction according to an example embodiment;

FIG. 9 is a cross-sectional view of a chip stacked structure in a Y direction according to an example embodiment;

FIG. 10 is a top view of a package substrate according to an example embodiment;

FIG. 11 is a top view of a chip stacked structure according to an example embodiment;

FIG. 12 is another schematic diagram of offset between a first chip and a second chip according to an example embodiment;

FIG. 13 is another cross-sectional view of a chip stacked structure in an X direction according to an example embodiment;

FIG. 14 is another top view of a package substrate according to an example embodiment; and

FIG. 15 is a schematic diagram of an electronic device according to an example embodiment.

### DESCRIPTION OF EMBODIMENTS

The technical solutions of the present disclosure are further described below in detail with reference to the accompanying drawings and the embodiments. Although example implementation methods of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily describe a specific order or sequence.

In the embodiments of the present disclosure, the term “layer” refers to a material part including a region having the thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. The layer may include multiple sublayers.

It should be noted that the technical solutions described in the embodiments of the present disclosure may be arbitrarily combined when there is no conflict.

In a related technology, to increase a storage capacity of a semiconductor product, semiconductor chips can be stacked. However, as a quantity of semiconductor chips increases, electrical connections between these semiconductor chips become relatively complex, which also leads to signal losses of the semiconductor chips.

In view of the foregoing technical problem, embodiments of the present disclosure provide a chip stacked structure. The chip stacked structure can improve complexity of an electrical connection and reduce a signal loss.

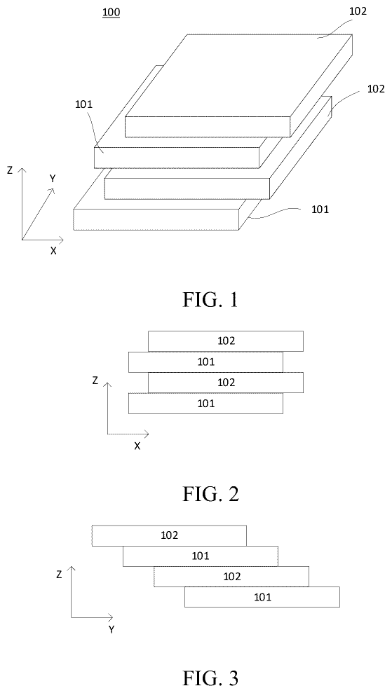

As shown in FIG. 1, an embodiment of the present disclosure provides a chip stacked structure 100. The chip stacked structure 100 may include multiple semiconductor chips stacked in a vertical direction (a Z direction). For example, in FIG. 1, the chip stacked structure 100 includes four semiconductor chips stacked in the vertical direction. Certainly, the chip stacked structure 100 may include at least two semiconductor chips, that is, include multiple semiconductor chips. The multiple semiconductor chips may be memory semiconductor chips. Each of the memory semiconductor chips may be, for example, a volatile memory semiconductor chip (such as a dynamic random access memory (DRAM) or a static random access memory (SRAM)) or a non-volatile memory semiconductor chip (such as a phase change random access memory (PRAM), a magnetoresistive random access memory (MRAM), a ferroelectric random access memory (FeRAM), or a resistive random access memory (RRAM)). According to some example embodiments, the multiple semiconductor chips may be flash memories, such as NAND flash memories. According to another example embodiment, the multiple semiconductor chips included in the chip stacked structure 100 may include different types of semiconductor chips. For example, some of the multiple semiconductor chips may be logic chips, and other semiconductor chips may be memory chips. For example, each of the logic chips may be a central processing unit (CPU) chip, a graphics processing unit (GPU) chip, or an application processor (AP) chip. The multiple semiconductor chips may have the same size. For example, the multiple semiconductor chips may have the same horizontal width, the same vertical width, and the same thickness.

As shown in FIG. 1 and FIG. 2, the chip stacked structure 100 includes, for example, two first chips 101 located on odd-numbered layers and two second chips 102 located on even-numbered layers. In this embodiment of the present disclosure, an odd-numbered layer, an even-numbered layer, an odd-numbered layer, and an even-numbered layer may be defined in sequence in the vertical direction from bottom to top, so that the first chips 101 and the second chips 102 alternate with each other. In a first direction (an X direction), a second chip 102 on an even-numbered layer is located on a first chip 101 on an odd-numbered layer, and the second chip 102 is offset from the first chip 101 to the right, so that the second chip 102 exceeds a side surface of the first chip 101, that is, a part of the second chip 102 protrudes from the first chip 101 in the first direction. In the first direction, the side surfaces of the two first chips 101 are aligned, that is, in the first direction, any one of the two first chips 101 does not exceed the other chip. In the first direction, side surfaces of the two second chips 102 are aligned, that is, in the first direction, any one of the two second chips 102 does not exceed the other chip.

As shown in FIG. 1 to FIG. 3, in a second direction (a Y direction), the two second chips 102 and the two first chips 101 are offset from each other in sequence, so that each semiconductor chip extends beyond a side surface of a semiconductor chip below the semiconductor chip. That is, the second chip 102 may be stacked on the first chip 101 arranged below the second chip 102, so that a part of the second chip 102 protrudes from the first chip 101 in the second direction (the Y direction). That is, the first chip 101 may be stacked on the second chip 102 arranged below the first chip 101, so that a part of the first chip 101 protrudes from the second chip 102 in the second direction (the Y direction). For example, the first chip 101 and the second chip 102 may be stacked on each other in a stepped manner, that is, in the Y direction, an offset amount of the second chip 102 relative to the first chip 101 is equal to an offset amount of the first chip 101 relative to the second chip 102.

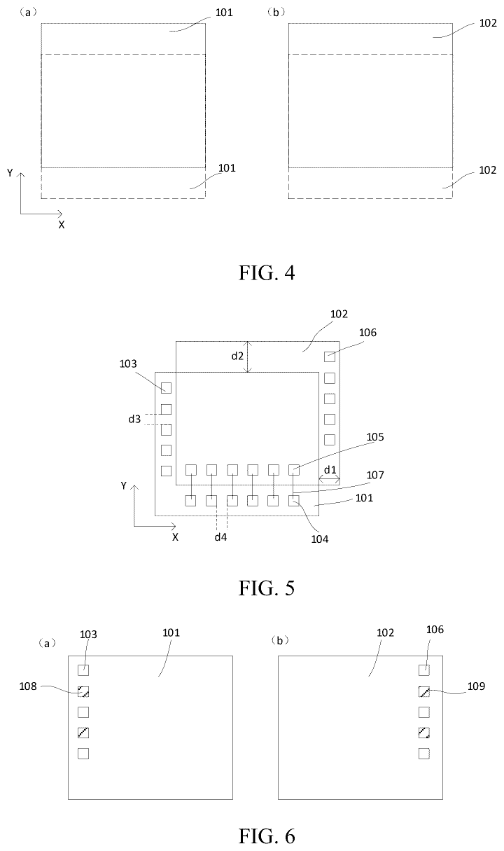

As shown in FIG. 1 and FIG. 4, in this embodiment of the present disclosure, (a) in FIG. 4 is a top view of the multiple first chips 101. A dash-line figure may represent a projection region of the lower first chip 101, and a solid-line figure may represent a projection region of the upper first chip 101. As can be seen from (a) in FIG. 4, the two projection regions are aligned in the X direction and offset in the Y direction in sequence, that is, a part of the upper first chip 101 protrudes from the side surface of the lower first chip 101. (b) in FIG. 4 is a top view of the multiple second chips 102. A dash-line figure may represent a projection region of the lower second chip 102, and a solid-line figure may represent a projection region of the upper second chip 102. As can be seen from (b) in FIG. 4, the two projection regions are aligned in the X direction and offset in the Y direction in sequence, that is, a part of the upper second chip 102 protrudes from the side surface of the lower second chip 102.

In some embodiments, the X direction and the Y direction may be interchangeable. In this case, the projection regions of the first chips 101 may be offset in the X direction, and the projection regions of the second chips 102 may also be offset in the X direction.

As shown in FIG. 5, FIG. 5 is a top view of the second chip 102 and a top view of the first chip 101. In the first direction (the X direction), the second chip 102 is offset from the first chip 101, so that multiple first signal pads 103 on the first chip 101 are exposed, and these first signal pads 103 may be arranged in the second direction (the Y direction). These first signal pads 103 may be arranged along an edge of the first chip 101. In this embodiment of the present disclosure, each of the first signal pads 103 is, for example, configured to transmit an I/O signal, a DQS signal, a CE signal, an RE signal, a WE signal, a CLE signal, an ALE signal, an R/B signal, and the like. In the second direction (the Y direction), the second chip 102 is offset from the first chip 101, so that multiple first common pads 104 on the first chip 101 are exposed, and these first common pads 104 may be arranged in the first direction. These first common pads 104 may be arranged along an edge of the first chip 101. Because the first direction is perpendicular to the second direction, the first signal pads 103 and the first common pads 104 may be disposed on adjacent edges of the first chip 101. In this embodiment of the present disclosure, the first common pads 104 may provide a ground voltage, a power supply voltage, and an address signal.

As shown in FIG. 5, in some embodiments, multiple second common pads 105 are also disposed on the second chip 102, the second common pads 105 are disposed on an edge of the second chip 102, and the second common pads 105 may be arranged in the first direction. Multiple second signal pads 106 are also disposed on the second chip 102, and the second signal pads 106 may be disposed on an edge of the second chip 102. The second signal pads 106 are, for example, located on an edge that is of the second chip 102 and that is away from the first signal pads 103, and the second signal pads 106 may be arranged in the second direction, thereby facilitating wire bonding for the second signal pads 106 on the second chip 102. The second common pads 105 may provide a ground voltage, a power supply voltage, and an address signal. Each of the second signal pads 106 is, for example, configured to transmit an I/O signal, a DQS signal, a CE signal, an RE signal, a WE signal, a CLE signal, an ALE signal, an R/B signal, and the like.

As shown in FIG. 5, the second common pads 105 are located on an edge that is of the second chip 102 and that is close to the first chip 101, that is, both the first common pads 104 and the second common pads 105 are arranged in the first direction. A quantity of the first common pads 104 may be equal to a quantity of the second common pads 105, and both the first common pads 104 and the second common pads 105 may transmit the same common signal to the first chip 101 and the second chip 102, so that the first common pads 104 and the second common pads 105 may be in a one-to-one correspondence, and each of the first common pads 104 and each of the second common pads 105 are connected through a lead 107. Because the multiple first common pads 104 and the multiple second common pads 105 are in a one-to-one correspondence, the lead 107 between one of the first common pads 104 and one of the second common pads 105 may be perpendicular to the first direction. The lead 107 may be perpendicular to the first direction, so that an electrical connection between the first chip 101 and the second chip 102 is relatively simple, and the length of the lead 107 can be reduced, thereby improving a signal loss. If the first common pads 104 and the second common pads 105 are not in a one-to-one correspondence, that is, the second common pads 105 are offset from the first common pads 104, the lead 107 between one of the first common pads 104 and one of the second common pads 105 cannot be perpendicular to the first direction, so that an electrical connection between the first chip 101 and the second chip 102 becomes relatively complex, and the length of the lead 107 increases, thereby leading to more signal loss. It should be noted that “vertical” herein may be vertical in a plane relationship, or may be vertical in a spatial relationship. Therefore, in this embodiment, the lead 107 may be perpendicular to the first direction in a plane relationship, or may be perpendicular to the first direction in a spatial relationship.

As shown in FIG. 5, in the first direction, the second chip 102 has a first offset amount d1 relative to the first chip 101, and the first offset amount d1 enables these first signal pads 103 on the first chip 101 to be fully exposed. The first offset amount d1 may be a distance between the right edge of the first chip 101 and the right edge of the second chip 102 in the first direction. The first offset amount d1 may alternatively be a distance between the left edge of the first chip 101 and the left edge of the second chip 102 in the first direction. In the second direction, the second chip 102 has a second offset amount d2 relative to the first chip 101, and the second offset amount d2 enables these first common pads 104 on the first chip 101 to be fully exposed. The second offset amount d2 may be a distance between the upper edge of the first chip 101 and the upper edge of the second chip 102 in the second direction. The second offset amount d2 may alternatively be a distance between the lower edge of the first chip 101 and the lower edge of the second chip 102 in the second direction.

As shown in FIG. 5, in some embodiments, the first offset amount d1 may be less than the second offset amount d2. The second chip 102 is offset in the first direction, so that the first signal pads 103 on the first chip 101 are exposed, and the second chip 102 is offset in the second direction, so that the first common pads 104 on the first chip 101 are exposed. The first signal pads 103 on the first chip 101 and the second signal pads 106 on the second chip 102 need to be separately wire-bonded to a substrate, and each of the first common pads 104 on the first chip 101 needs to be wire-bonded to each of the second common pads 105 on the second chip 102. Therefore, to reduce a wire bonding difficulty of each of the first common pads 104 and each of the second common pads 105, the second offset amount d2 may be greater than the first offset amount d1. If the second offset amount d2 is less than the first offset amount d1, in the second direction, a spacing between one of the first common pads 104 and one of the second common pads 105 decreases, which is inconducive to a wire bonding process.

In some embodiments, when a value range of both the first offset amount d1 and the second offset amount d2 exceeds 200 μm, e.g., 220-260 μm, the first offset amount d1 may be equal to the second offset amount d2. Therefore, a design of the chip stacked structure 100 is relatively simple, and complexity of an electrical connection between chips can be further reduced.

As shown in FIG. 5, the multiple first signal pads 103 are disposed at intervals on an edge of the first chip 101, for example, one column of first signal pads 103 is disposed on the edge of the first chip 101. The multiple first common pads 104 are disposed at intervals on an edge of the first chip 101, for example, one row of first common pads 104 is disposed on the edge of the first chip 101. The one column of first signal pads 103 and the one row of first common pads 104 are located on adjacent edges of the first chip 101. There is a spacing d3 between two adjacent first signal pads 103, and there is a spacing d4 between two adjacent first common pads 104. In some embodiments, the first offset amount d1 may be greater than the spacing d3, and the spacing d3 may be greater than the spacing d4. Because the first offset amount d1 is relatively small, the spacing d3 between two adjacent first signal pads 103 may be relatively small, and in this case, more first signal pads 103 may be disposed on the edge of the first chip 101. In addition, it can be ensured that when the first signal pads 103 transmit signals, signal crosstalk is avoided. The spacing d4 between two adjacent first common pads 104 is smaller. Because the first common pads 104 are configured to transmit signals such as a power supply voltage or a ground voltage, a problem such as signal crosstalk does not occur.

As shown in FIG. 6, in some embodiments, to improve signal crosstalk between data signals, multiple first ground pads 108 may also be disposed on the first chip 101, and the first ground pads 108 may be disposed between adjacent ones of the first signal pads 103 at intervals. Multiple second ground pads 109 may also be disposed on the second chip 102, and the second ground pads 109 may be disposed between adjacent ones of the second signal pads 106 at intervals.

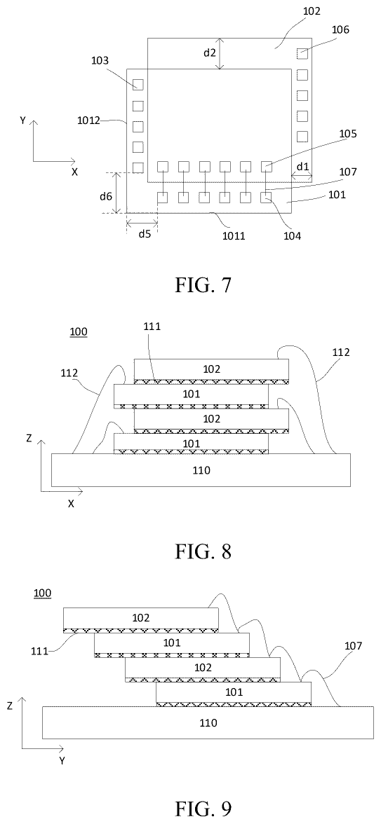

As shown in FIG. 7, the first common pads 104 may be disposed on a first edge 1011 of the first chip 101. The first signal pads 103 may be disposed on a second edge 1012 of the first chip 101. In the first direction, the second chip 102 has a first offset amount d1 relative to the first chip 101. In this case, the shortest distance d5 from the second edge 1012 to the first common pads 104 may be greater than the first offset amount d1. In addition, in the second direction, the second chip 102 has a second offset amount d2 relative to the first chip 101. In this case, the shortest distance d6 from the first edge 1011 to the first signal pads 103 may be greater than the second offset amount d2. It should be noted that the shortest distance d5 from the second edge 1012 to the first common pads 104 may be understood as a distance from the first common pad 104 closest to the second edge 1012 to the second edge 1012. The shortest distance d6 from the first edge 1011 to the first signal pads 103 may be understood as a distance from the first signal pad 103 closest to the first edge 1011 to the first edge 1011. In this embodiment, in the first direction, the shortest distance d5 is greater than the first offset amount d1, so as to ensure a one-to-one correspondence between the common pads on the first chip 101 and the second chip 102, and further ensure that the lead can be perpendicular to the first direction. In addition, in the second direction, by enabling the shortest distance d6 to be greater than the second offset amount d2, it can be ensured that these first signal pads 103 are relatively concentrated in some regions of the second edge 1012, thereby facilitating a wiring path between each of the first signal pads 103 and another pad.

As shown in FIG. 8 to FIG. 10, in some embodiments, the chip stacked structure 100 may further include a package substrate 110. The first chip 101 may be mounted on the package substrate 110 through a first bonding layer 111, and then the second chip 102 is mounted on the first chip 101 through a first bonding layer 111. Each of the first signal pads 103 on the first chip 101 may be connected to a first substrate signal pad 114 on the package substrate 110 through a first lead 112, and each of the second signal pads 106 on the second chip 102 may be connected to a second substrate signal pad 115 on the package substrate 110 through a first lead 112. At least one column of first substrate signal pads 114 may be disposed on the package substrate 110, and at least one column of second substrate signal pads 115 may be further disposed. Because the first signal pads 103 on the multiple first chips 101 are separately connected to the package substrate 110, multiple columns of first substrate signal pads 114 may be disposed on the package substrate 110, that is, a quantity of columns of the first substrate signal pads 114 may be equal to a quantity of the first chips 101. Because the second signal pads 106 on the multiple second chips 102 are separately connected to the package substrate 110, multiple columns of second substrate signal pads 115 may be disposed on the package substrate 110, that is, a quantity of columns of the second substrate signal pads 115 may be equal to a quantity of the second chips 102. In this embodiment, the first bonding layer 111 may be a die attach film (DAF). Because the thickness of the first bonding layer 111 is relatively small, the first lead 112 cannot be covered. Therefore, in this embodiment, an offset stacking manner is adopted to ensure that the signal pads on the first chip 101 and the second chip 102 can all be electrically connected to the package substrate 110. Because the thickness of the DAF is small, the overall thickness of the chip stacked structure can be reduced. In addition, a thermal conductivity of the material is less than a thermal conductivity of the first chip 101, so that a heat dissipation effect of the chip stacked structure is improved.

As shown in FIG. 8 to FIG. 10, each of the first common pads 104 on the first chip 101 is connected to each of the second common pads 105 on the second chip 102 through a lead 107, and then each of the first common pads 104 on the first chip 101 is connected to a substrate common pad 113 on the package substrate 110 through a lead 107. Because the substrate common pad 113 may provide a power supply voltage and/or a ground voltage, these chips may be connected through the lead 107 and then connected to the package substrate 110. As can be seen from FIG. 9, the lead 107 may be spatially perpendicular to the first direction, thereby reducing difficulty of an electrical connection between these chips and reducing a signal loss.

As shown in FIG. 11, FIG. 11 is a top view of the chip stacked structure 100. FIG. 11 shows only a top view of the lead 107. In FIG. 11, the lead 107 connects the first chip 101, the second chip 102, and the package substrate 110. The lead 107 is perpendicular to the first direction in a plane. In this embodiment, in a stacking process of the first chip 101 and the second chip 102, the first common pads 104 and the second common pads 105 are in a one-to-one correspondence, and it is ensured that the lead 107 between one of the first common pads 104 and one of the second common pads 105 can be perpendicular to the first direction, that is, the lead 107 is prevented from being inclined relative to the first direction, thereby improving complexity of an electrical connection between the first chip 101 and the second chip 102, and improving a signal loss. If the first common pads 104 on the first chip 101 are not in a one-to-one correspondence with the second common pads 105 on the second chip 102, in this case, the lead 107 between one of the first common pads 104 and one of the second common pads 105 is inclined relative to the first direction, which increases a wire bonding difficulty and a wire bonding length, thereby being inconducive to an electrical connection between the first chip 101 and the second chip 102.

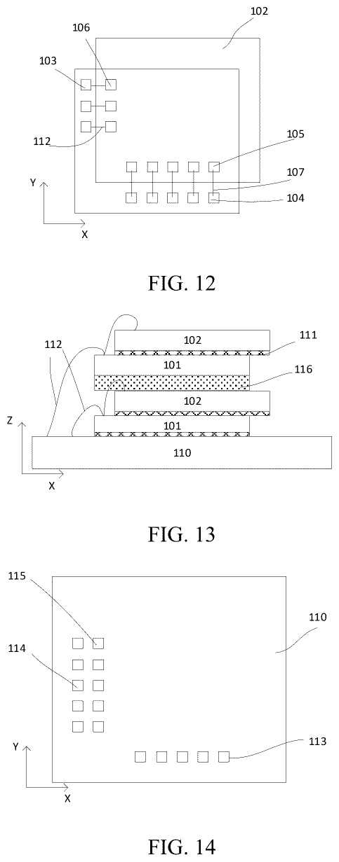

As shown in FIG. 12, an embodiment of the present disclosure further provides another chip stacked structure 100. The chip stacked structure 100 may include a first chip 101 and a second chip 102. The second chip 102 is disposed on the first chip 101 in an offset manner. In a first direction, the second chip 102 is offset from the first chip 101, so that first signal pads 103 on the first chip 101 are exposed. In a second direction, the second chip 102 is offset from the first chip 101, so that first common pads 104 on the first chip 101 are exposed. Second common pads 105 and second signal pads 106 are also disposed on the second chip 102. The second common pads 105 are disposed parallel to the first common pads 104. The second common pads 105 are located on an edge that is of the second chip 102 and that is close to the first chip 101. The second common pads 105 and the first common pads 104 may be in a one-to-one correspondence, so that a lead 107 between one of the first common pads 104 and one of the second common pads 105 can be perpendicular to the first direction, thereby improving complexity of an electrical connection between the first chip 101 and the second chip 102. The second signal pads 106 are located on an edge that is of the second chip 102 and that is close to each of the first signal pads 103, so that the first signal pads 103 are arranged parallel to the second signal pads 106. Therefore, the first signal pads 103 and the second signal pads 106 are in a one-to-one correspondence, so that a first lead 112 between each of the first signal pads 103 and each of the second signal pads 106 can be perpendicular to the second direction, thereby improving complexity of an electrical connection between the first chip 101 and the second chip 102.

As shown in FIG. 12 and FIG. 13, in some embodiments, the chip stacked structure 100 may further include a package substrate 110. The 1st first chip 101 may be mounted on the package substrate 110 through a first bonding layer 111, and the 1st second chip 102 may be mounted on the 1st first chip 101 through a first bonding layer 111. The 2nd first chip 101 may be mounted on the 1st second chip 102 through a second bonding layer 116, and the 2nd second chip 102 may be mounted on the 2nd first chip 101 through a first bonding layer 111. The thickness of the first bonding layer 111 may be less than the thickness of the second bonding layer 116, so that the second bonding layer 116 can cover the first lead 112. Each of the second signal pads 106 on the second chip 102 is connected to each of the first signal pads 103 on the first chip 101 through a first lead 112, and then is connected to each of the signal pads on the package substrate 110 through a first lead 112. Because each of the signal pads of the first chip 101 and each of the signal pads of the second chip 102 are connected through the first lead 112, a signal path between the first chip 101 and the second chip 102 can be reduced, thereby improving a signal time difference between the first chip 101 and the second chip 102. In this embodiment, the second bonding layer 116 may be a film over wire (FOW).

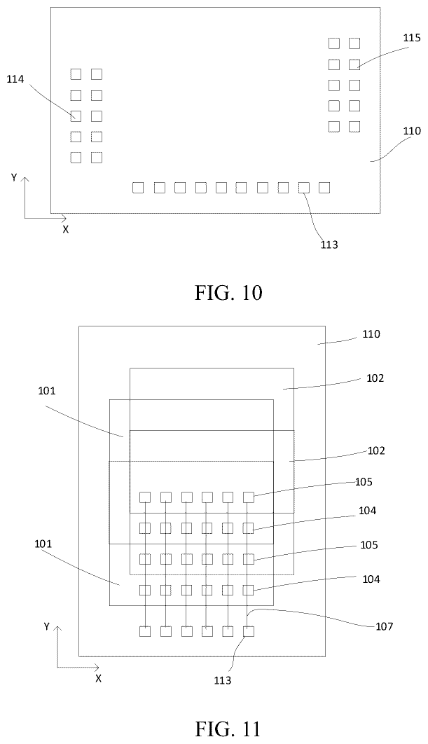

As shown in FIG. 14, FIG. 14 is a top view of the package substrate 110 in FIG. 13. A difference between FIG. 14 and FIG. 10 lies in that the first substrate signal pads 114 and the second substrate signal pads 115 in FIG. 14 are located on the same side of the package substrate 110, and each of the first substrate signal pads 114 and each of the second substrate signal pad 115 are connected to the first chip 101 through a first lead 112. Because the first substrate signal pads 114 and the second substrate signal pads 115 are located on the same side of the package substrate 110, the volume of the package substrate 110 can be reduced, thereby reducing the volume of the chip stacked structure 100. Each of the substrate common pads 113 on the package substrate 110 may be connected to the first chip 101 and the second chip 102 through a lead. For a connection relationship, refer to the lead 107 in FIG. 11. In some embodiments, the package substrate 110 may be any of various types of substrates, such as a printed circuit board (PCB), an organic substrate, an inorganic substrate, a glass substrate, or a flexible substrate. In addition, the package substrate 110 may be a substrate configured for various types of electronic devices, such as a mobile device, a memory device, a display device, or a display driver integrated circuit (DDI). The package substrate 110 may be a multi-layer (printed) circuit board having a via hole and various circuit patterns connected to the via hole.

As shown in FIG. 7 and FIG. 11, an embodiment of the present disclosure further provides a package structure. The package structure may include a package substrate 110. Substrate common pads 113 are disposed on the package substrate 110, the substrate common pads 113 are arranged in a first direction, and the substrate common pads 113 are located on an edge of the package substrate 110. A first chip 101 and a second chip 102 that are stacked on each other in sequence are disposed on the package substrate 110. In a first direction (an X direction), the second chip 102 is offset from the first chip 101, so that first signal pads 103 on the first chip 101 are exposed, that is, the first signal pads 103 are arranged in a second direction. In the second direction (a Y direction), the second chip 102 is offset from the first chip 101, so that first common pads 104 on the first chip 101 are exposed, that is, the first common pads 104 are arranged in the first direction. Second common pads 105 are also disposed on the second chip 102, and the second common pads 105 are arranged in the first direction. The second common pads 105 are located on an edge that is of the second chip 102 and that is close to the first common pads 104, so that the first common pads 104 and the second common pads 105 are in a one-to-one correspondence. In addition, the substrate common pads 113 may also be in a one-to-one correspondence with the first common pads 104. Therefore, when a lead 107 is adopted to connect the package substrate 110, the first chip 101, and the second chip 102, the lead 107 can be perpendicular to the first direction, thereby improving complexity of an electrical connection between the first chip 101, the second chip 102, and the package substrate 110. For a cross-sectional view of FIG. 14 in the X or Y direction, refer to FIG. 8 and FIG. 9.

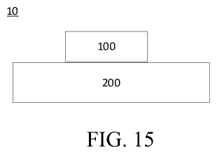

As shown in FIG. 15, this embodiment of the present disclosure further discloses an electronic device 10. The electronic device 10 may include a mainboard 200 and a chip stacked structure 100, and the chip stacked structure 100 may be fastened to the mainboard 200 through a solder ball. For a structure of the chip stacked structure 100, refer to the foregoing description. The electronic device 10 may include one or more of the following: e.g., a smart phone, a tablet personal computer (PC), a mobile phone, a video phone, an e-book (e-book) reader, a desktop PC, a laptop PC, a netbook computer, a workstation, a server, a personal digital assistant (PDA), a portable multimedia player (PMP), an MPEG-1 audio layer 3 (MP3) player, a mobile medical device, a camera, a home appliance, a medical device, an Internet of Things (IoT) device, and a wearable device. The wearable device may be of an accessory type, a fabric or clothing type, a body attachment type, or an implantable circuit type. An accessory-type wearable device may be, e.g., a watch, a ring, a bracelet, an anklet, a necklace, glasses, contact lenses, or a head-mounted device (HMD). The electronic device 10 may be further applied to a large server, such as a data center or an AI computer. The electronic device 10 may further be applied to a personal navigation apparatus or a portable navigation apparatus (PND), a hand-held game console, a mobile Internet apparatus (MID), a wearable computer, an Internet of Things (IoT) apparatus, an Internet of Everything (IoE) apparatus, and/or a drone.

In conclusion, embodiments of the present disclosure provide a chip stacked structure, a package structure, and an electronic device. The chip stacked structure adopts an offset stacking manner, so that a second chip is offset from a first chip in both a first direction and a second direction. However, multiple first common pads on the first chip and multiple second common pads on the second chip are in a one-to-one correspondence, and a lead between one of the first common pads and one of the second common pads is perpendicular to the first direction, so that an electrical connection between the two chips is relatively simple. In addition, a signal path between the two chips can be reduced, and a signal loss can be reduced.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A chip stacked structure, wherein:
in a first direction, a second chip located on an even-numbered layer is offset from a first chip located on an odd-numbered layer to expose a plurality of first signal pads on the first chip on the odd-numbered layer, and the plurality of first signal pads are arranged in a second direction;
in the second direction (Y), the second chip located on the even-numbered layer is offset from the first chip located on the odd-numbered layer to expose a plurality of first common pads on the first chip on the odd-numbered layer, the plurality of first signal pads are arranged in the first direction, and the first direction is perpendicular to the second direction; and
a plurality of second common pads on the second chip are arranged in the first direction, the plurality of second common pads are located on an edge that is of the second chip and that is close to the first common pads, each of the first common pads is corresponding to each of the second common pads, and a lead between one of the first common pads and one of the second common pads is perpendicular to the first direction.

2. The chip stacked structure according to claim 1, wherein the chip stacked structure comprises a plurality of first chips and a plurality of second chips, and in a vertical direction, projection regions of the plurality of first chips are offset in sequence, and projection regions of the plurality of second chips are offset in sequence.

3. The chip stacked structure according to claim 1, wherein in the first direction, the second chip has a first offset amount relative to the first chip, in the second direction, the second chip has a second offset amount relative to the first chip, and the first offset amount is less than the second offset amount.

4. The chip stacked structure according to claim 3, wherein the first offset amount is greater than a spacing between adjacent ones of the first signal pads.

5. The chip stacked structure according to claim 1, wherein a spacing between adjacent ones of the first signal pads is greater than a spacing between adjacent ones of the first common pads.

6. The chip stacked structure according to claim 1, wherein the second chip further comprises a plurality of second signal pads, the plurality of second signal pads being arranged in the second direction, and the plurality of second signal pads being located on an edge that is of the second chip and that is away from the first signal pads.

7. The chip stacked structure according to claim 6, wherein the first chip further comprises a first ground pad, the first ground pad being located between adjacent ones of the plurality of first signal pads; and the second chip further comprises a second ground pad, the second ground pad being located between adjacent ones of the plurality of second signal pads.

8. The chip stacked structure according to claim 1, wherein the second chip further comprises a plurality of second signal pads, the plurality of second signal pads being arranged in the second direction, and the plurality of second signal pads being located on an edge that is of the second chip and that is close to the first signal pads.

9. The chip stacked structure according to claim 8, wherein each of the second signal pads on the second chip is connected to one of the first signal pads on the first chip through a lead.

10. The chip stacked structure according to claim 3, wherein the first common pads are located on a first edge of the first chip, and a shortest distance from the first edge to the first signal pads is greater than the second offset amount.

11. The chip stacked structure according to claim 3, wherein the first signal pads are located on a second edge of the first chip, and a shortest distance from the second edge to the first common pads is greater than the first offset amount.

12. The chip stacked structure according to claim 6, further comprising a package substrate, a plurality of substrate common pads being disposed on the package substrate, and each of the substrate common pads being connected to one of the first common pads through a lead.

13. The chip stacked structure according to claim 12, wherein at least one column of first substrate signal pads is further disposed on the package substrate, the at least one column of first substrate signal pads being arranged parallel to the plurality of first signal pads, and each of the first signal pads on the first chip being connected to each of the first substrate signal pads through a lead.

14. A package structure, comprising:
a package substrate, comprising a plurality of substrate common pads; and
a plurality of chips, stacked on the package substrate;
in a first direction (X), a second chip located on an even-numbered layer being offset from a first chip located on an odd-numbered layer to expose a plurality of first signal pads on the first chip on the odd-numbered layer, the plurality of first signal pads being arranged in a second direction;
in the second direction (Y), the second chip located on the even-numbered layer being offset from the first chip located on the odd-numbered layer to expose a plurality of first common pads on the first chip on the odd-numbered layer, the plurality of first signal pads being arranged in the first direction, and the first direction being perpendicular to the second direction;
a plurality of second common pads on the second chip being arranged in the first direction, the plurality of second common pads being located on an edge that is of the second chip and that is close to the first common pads, each of the first common pads corresponding to each of the second common pads, and a lead between one of the first common pads and one of the second common pads being perpendicular to the first direction; and
each of the substrate common pads corresponding to each of the first common pads, and a lead between each of the substrate common pads and each of the first common pads being perpendicular to the first direction.

15. The package structure according to claim 14, wherein in the first direction, the second chip has a first offset amount relative to the first chip, in the second direction, the second chip has a second offset amount relative to the first chip, and the first offset amount is less than the second offset amount.

16. The package structure according to claim 15, wherein the first offset amount is greater than a spacing between adjacent ones of the first signal pads.

17. The package structure according to claim 14, wherein a spacing between adjacent ones of the first signal pads is greater than a spacing between adjacent ones of the first common pads.

18. The package structure according to claim 14, wherein the second chip further comprises a plurality of second signal pads, the plurality of second signal pads being arranged in the second direction, and the plurality of second signal pads being located on an edge that is of the second chip and that is away from the first signal pads.

19. The package structure according to claim 18, wherein the first chip further comprises a first ground pad, the first ground pad being located between adjacent ones of the plurality of first signal pads; and the second chip further comprises a second ground pad, the second ground pad being located between adjacent ones of the plurality of second signal pads.
